(19) United States
(12) Patent Application Publication
(10) Pub. No.: US 2008/0311757 A1
(43) Pub. Date: Dec. 18, 2008

(54) SYSTEM AND METHOD FOR CHEMICAL DRY ETCHING SYSTEM

(75) Inventors: Li Wei Dong, Shanghai (CN); Shen Xiang Jiang, Shanghai (CN); Zhou Run Feng, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Pudong New Area (CN)

(21) Appl. No.: 12/135,006

(22) Filed: Jun. 6, 2008

(30) Foreign Application Priority Data
Jun. 18, 2007 (CN) 200710042161.7

(51) Int. Cl. H01L 21/3065

(52) U.S. Cl. 438/710; 156/345.26; 257/E21.218

(57) ABSTRACT

A system and method for chemical dry etching system. The present invention provides a method for performing an etching process for manufacture of integrated circuits. The method includes providing a semiconductor wafer. The method also includes the step of maintaining the semiconductor wafer in a predetermined environment. The method includes subjecting a portion of the layer to a plasma environment. The plasma environment includes one or more plasma species. For example, the plasma species are used to perform etching. The method also includes monitoring a pressure condition within a first transport device using a sensing device. The sensing device is spatially configured between a valve and a pumping device. The valve is coupled to a second exhaust coupled to the plasma chamber. The method additionally includes determining if the pressure condition within the first exhaust is within a predetermined condition. The method includes removing the one or more plasma species through the first exhaust, through the valve, and through the second exhaust if the pressure condition within the first exhaust is within the predetermined condition.

### CROSS-REFERENCES TO RELATED APPLICATIONS

This application claims priority to Chinese Patent No. 200710042161.7, filed Jun. 18, 2007 (SMIC Docket No. 1-05-200), commonly assigned and hereby incorporated by reference for all purposes.

### BACKGROUND OF THE INVENTION

The present invention is directed to integrated circuits and their processing for the manufacture of semiconductor devices. More particularly, the invention provides a method and device for the etching process for the manufacture of integrated circuits. Merely by way of example, the invention has been applied to the chemical dry etching process for the manufacture of integrated circuits. But it would be recognized that the invention has a much broader range of applicability. For example, the invention can be applied to the chemical drying etching systems, such as those manufactured by Shibaura Mechatronics Corporation.

Integrated circuits or “ICs” have evolved from a handful of interconnected devices fabricated on a single chip of silicon to millions of devices. Current ICs provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of ICs. Semiconductor devices are now being fabricated with features less than a quarter of a micron across.

Increasing circuit density has not only improved the complexity and performance of ICs but has also provided lower cost parts to the consumer. An IC fabrication facility can cost hundreds of millions, or even billions, of dollars. Each fabrication facility will have a certain throughput of wafers, and each wafer will have a certain number of ICs on it. Therefore, by making the individual devices of an IC smaller, more devices may be fabricated on each wafer, thus increasing the output of the fabrication facility. Making devices smaller is very challenging, as each process used in IC fabrication has a limit. That is to say, a given process typically only works down to a certain feature size, and then either the process or the device layout needs to be changed. An example of such a limit is chemical dry etching process used for the manufacture of integrated circuits in a cost effective and efficient way.

The manufacturing of integrated circuits involves various processes. For example, the processes include, inter alia, wafer growth, photolithography, doping, oxidation, deposition, etching Removal, and epitaxial Growth.

Etching is an important process in semiconductor manufacturing. Etching involves removing selected regions from the surface of a wafer using physical process, chemical process, or the combination thereof. Usually the goal of etching is to faithfully reproduce masking patterns. To achieve this goal, it is often desirable to for the etching process to be highly selective both in patterns and depth, which is often achieve through chemical dry etching.

Chemical drying etching usually involves generating reactive species in a plasma, diffusing these species to the surface of material being etched, species being absorbed, reacting of these species on the surface to form volatile by-product, absorbing or the by-product by the surface, and diffusing of the desorbed species diffusing into gas. There are many various dry-etch systems to accomplish these steps. For example, dry-etch systems include barrel etchers, downstream etchers, parallel-electrode (planar) reactor etchers, stacked parallel-electrode etchers, hexode batch etchers, magnetron ion etchers, etc.

The present invention is related to downstream etchers. Downstream etchers create plasma for reactive species and then transport plasma to the etching chamber of the plasma. Often, microwave sources are used to create chemical species. Typically, downstream etchers operate in the high pressure range. For example, a dry etching system is capable of perform corner rounding, bevel etching, resist recess, mask removal, etc.

The operation of system exhaust is important for a downstream chemical dry etcher. While chemical dry etchers generally include system exhausts, system exhausts do not always function as desired.

Therefore an improved exhaust system for chemical dry etching is desired.

### BRIEF SUMMARY OF THE INVENTION

The present invention is directed to integrated circuits and their processing for the manufacture of semiconductor devices. More particularly, the invention provides a method and device for the etching process for the manufacture of integrated circuits. Merely by way of example, the invention has been applied to the chemical dry etching process for the manufacture of integrated circuits. But it would be recognized that the invention has a much broader range of applicability.

According to an embodiment, the present invention provides a chemical dry etching system, wherein one or more gas is induced into a first chamber (e.g., a quartz tube) and subjected to a microwave power source to cause formation of one or more plasma species. The one or more plasma species is then transferred from the first chamber to a second chamber. At the second chamber, at least one substrate is subjected to the one or more plasma species. Often, the one or more plasma species causes etching at the at least one substrate. The one or more plasma species is then disposed by an exhaust system after the at least one substrate is subjected to the one or more plasma species. The exhaust system includes a system controller. The system controller is configured to receive a plurality of feedback signals and provide a plurality of control signals. For example, the plurality of feedback signals allows the system controller to monitor the status of various components at of the chemical dry etching system. The system controller also includes a pumping device that is configured to turn on in response to a start signal of a plurality of control signals from the system controller and provide a verification signal of the plurality of feedback signals to the system controller. For example, the verification signal indication whether the pumping device is functioning properly. Additionally, the exhaust system includes a first valve, which is configured to open in response to a first signal of the plurality of control signals received from the system controller and close in response to a second signal of the plurality of control signals received from the system controller. In addition, the exhaust system includes a transport. The transport includes a first connection and a second connection. The first connection is connected to the first valve, and the second connection is connected to the pumping device. Moreover, the exhaust system includes a pressure gauge, which is configured to measure a pressure of the transport and provide a pressure signal of the plurality of feedback signals to the system controller. The pressure signal of the plurality of feedback signals is associated with the measured pressured of the transport.

According to another embodiment, the present invention provides a chemical dry etching system. At the chemical dry etching system, one or more gas is induced into a first chamber and subjected to a microwave power source to cause formation of one or more plasma species. The one or more plasma species is then transferred from the first chamber to a second chamber. At the second chamber at least one substrate is subjected to the one or more plasma species. The one or more plasma species is then disposed by an exhaust system after the at least one substrate is subjected to the one or more plasma species. A method for operating the exhaust system includes sending a first start signal from a system controller to a pumping device. The pumping device drains a plurality of gas from a transport. The method also includes the step of measuring a pressure in the transport by a pressure gauge after a first predetermined period after sending the first start signal. The pressure gauge is configured to measure the pressure at the transport. The method additionally includes the step of obtaining a plurality of data associated with the pressure by the system controller. Moreover, the method includes the step of determining whether the pressure is below a predetermined threshold pressure.

According to another embodiment, the present invention provides a method of manufacturing an integrated circuit device. The method includes providing a semiconductor wafer. The semiconductor wafer includes a surface region. The method additionally includes the step of using a plurality of plasma to form one or more portions of the surface region. The method also includes the step of disposing the plurality of plasma by an exhaust system after a first predetermined period. The exhaust system includes a system controller. The disposing the plurality of plasma includes the step of sending a first start signal from a system controller to a pumping device. The pumping device drains a plurality of gas from a transport. The disposing the plurality of plasma also includes measuring a pressure in the transport by a pressure gauge after a first predetermined period after sending the first start signal. The pressure gauge is configured to measure the pressure at the transport. Additionally, the disposing the plurality of plasma includes obtaining a plurality of data associated with the pressure by the system controller. In addition, the disposing the plurality of plasma includes determining whether the pressure is below a predetermined range of pressure values.

According to another embodiment, the present invention provides a method for performing an etching process for manufacture of integrated circuits. The method includes providing a semiconductor wafer. The semiconductor wafer includes a layer to be etched into a plasma chamber. The method also includes the step of maintaining the semiconductor wafer in a predetermined environment. For example, the predetermine environment is a vacuum environment. In addition, the method includes subjecting a portion of the layer to a plasma environment. The plasma environment includes one or more plasma species. For example, the plasma species are used to perform etching. The method also includes monitoring a pressure condition within a first transport device using a sensing device. The sensing device is spatially configured between a valve and a pumping device. The valve is coupled to a second exhaust coupled to the plasma chamber. The method additionally includes determining if the pressure condition within the first exhaust is within a predetermined condition. Moreover, the method includes removing the one or more plasma species through the first exhaust, through the valve, and through the second exhaust if the pressure condition within the first exhaust is within the predetermined condition.

Many benefits are achieved by way of the present invention over conventional techniques. For example, the present technique provides an easy to use process that relies upon conventional technology. Additionally, the method provides a process that is compatible with conventional process technology without substantial modifications to conventional equipment and processes. Depending upon the embodiment, one or more of these benefits may be achieved. These and other benefits will be described in more throughout the present specification and more particularly below.

According to certain embodiments, the present invention provides a dry etching system that is capable of effectively preventing contamination during the process of dry etching. For example, unwanted gases are prevented from entering into the process chamber of a chemical dry etcher and contaminating the wafers therein. According to an embodiment, the present invention is compatible with existing chemical dry etching processes.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram illustrating the DRY ETCHING system.

FIG. 2 is a simplified functional block diagram illustrating the system control flow for the exhaust portion of a conventional dry etching system.

FIG. 3 is a simplified block diagram illustrating the signal control flow for the exhaust portion of a conventional dry etching system.

FIG. 4 is a simplified block diagram illustrating standby exhaust sequence for a conventional dry etching system.

FIG. 5 is a simplified diagram illustrating an improved chemical dry etcher according to an embodiment of the present invention.

FIG. 6 is a simplified functional block diagram illustrating the system controller flow for the exhaustion portion of the chemical dry etcher.

FIG. 7 is a simplified block diagram illustrating the signal control flow for the exhaustion portion of the chemical dry etcher.

### DETAILED DESCRIPTION OF THE INVENTION

The present invention is directed to integrated circuits and their processing for the manufacture of semiconductor devices. More particularly, the invention provides a method and device for the etching process for the manufacture of integrated circuits. Merely by way of example, the invention has been applied to the chemical dry etching process for the manufacture of integrated circuits. But it would be recognized that the invention has a much broader range of applicability.

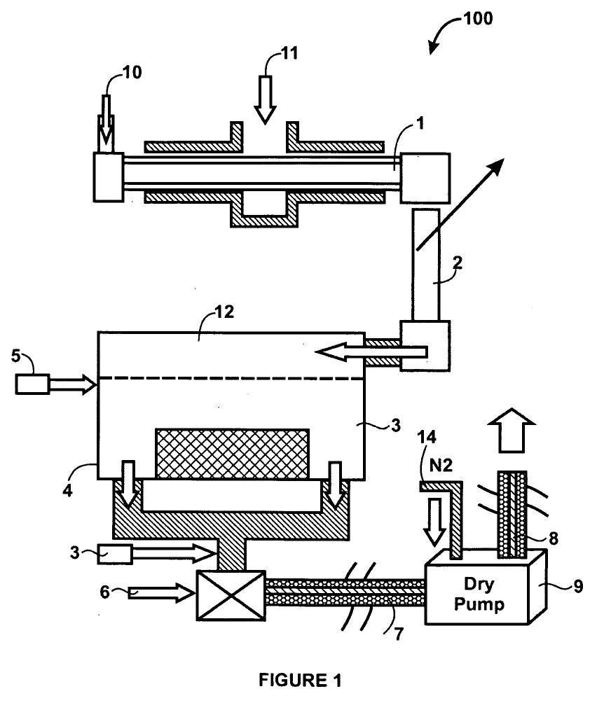

FIG. 1 is a simplified diagram illustrating the drying etching system. This diagram is merely an example, which should not unduly limit the scope of the claims. One of ordinary skill in the art would recognize many variations, alternatives, and modifications. The drying etching system 100 includes a gas inlet 10, a quartz tube 1, a microwave source 11, a teflon transport 2, a nozzle 12, a process chamber 3, a Baratron gauge controller 5, a Pirani gauge 3, a main valve 6, a pump line transport 7, a dry pump 9, and a system exhaust 8. For example, the drying etching system 100 is a CDE 300 system.

When the drying etching system 100 operates, a gas enters the gas inlet 10. For example, a gas could be various type of gases, including O₂, CF₄, etc. Next the gas enters the quartz tube 1. When the gas is in the quartz tube 1, the microwave source 11 emits microwaves on the gas. As an example, microwaves have a frequency of approximately 2.45 GHz. After being going through the microwave, the gas becomes a plasma. Then the plasma is transferred through the teflon transport 2 to the nozzle 12. From the nozzle, the plasma is applied to one or more wafers in the process chamber 3 for processing. There are many types of process that can be done at the process chamber. For example, processes include etching, corner rounding, bevel etching, resist recess, mask removal, etc. Usually, the pressure is high at the process chamber. The Baratron gauge controller 5 is used to monitor and control the pressure. Once the plasma has been used for processing, it is to be disposed. The main valve 6 controls whether, when, and how the plasma is to be disposed. A Pirani gauge 3 is used to monitor the pressure and flow of the plasma at the main valve. Pirani gauges use thermal conductivity to measure pressure and are mainly used for vacuum systems. Generally, the main valve 6 opens after the dry pump 9 has started so that gases, if there is any, in the pump line transport 7 would not enter the process chamber 3 and contaminate. Once the main valve 6 opens, the plasma flows through the pump line transport 7 and dry pump 9, and is then disposed at the system exhaust 8.

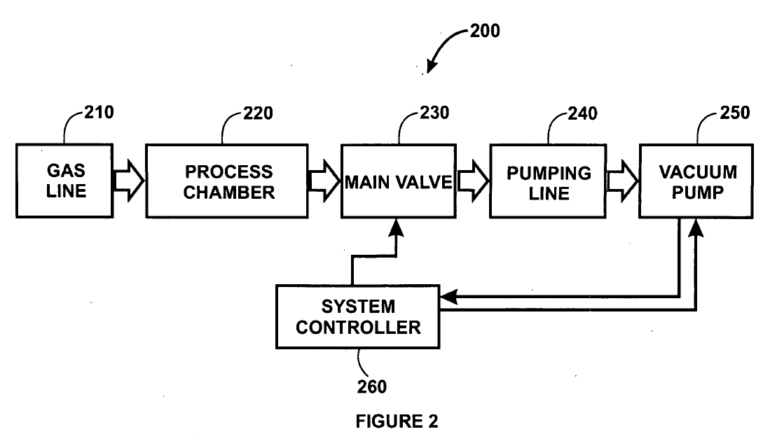

For the purpose of exhausting the processed plasma, a system controller is used to control the main valve 6 and the dry pump 9. FIG. 2 is a simplified functional block diagram illustrating the system control flow for the exhaust portion of the drying etching system. The exhaust system 200 includes a gas line 210, a process chamber 220, a main valve 230, a pump line 240, a dry pump 250, and a system controller 260. The system controller 260 is used to control both the dry pump 250 and the main valve 230. The control signals that system controller 260 send to the dry pump 250 and the main valve 230 are based on the signals that system controller 260 receives from the dry pump 250.

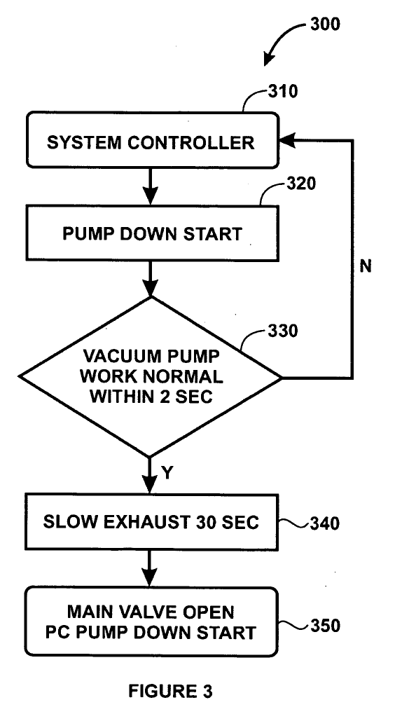

FIG. 3 is a simplified block diagram illustrating the signal control flow for the exhaust portion of the drying etching system. First the system controller 310 sends a start signal to the dry pump 320 to start the dry pump 320. Next dry pump 320 starts in response to the start signal. Two seconds later, the dry pump 320 determines whether the dry pump is working properly, which is determined at step 330. If the pump does not appear to be working properly, the dry pump 320 sends a signal to the system controller 310 to indicate that there might be a problem. On the other hand, if the dry pump 320 does appear to be working properly, the dry pump 320 sends a signal to the exhaust 340 to slow the exhaust for 30 seconds. During the 30 seconds of slowing the exhaust, most (if not all) gases that are in the pump line between the main valve and the exhausted are cleaned out of the pump line. Next, singles are sent to the main valve and the process chamber at step 350 to open the main valve and start process chamber pump down.

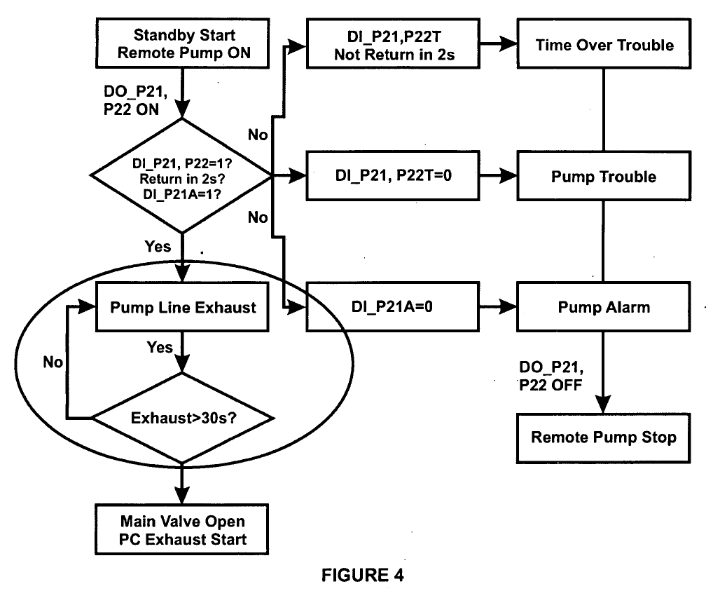

FIG. 4 is a simplified block diagram illustrating standby exhaust sequence for the dry etching system. More specifically, DI and DO signals are digital control signals used among different components the dry etching system.

As explained above, the drying etching system 100 in FIG. 1 performs chemical dry etching and disposes plasma that has been used in processing chamber from its exhaust pipe. The disposition of plasma is one of the crucial steps. If not conducted properly, the “waste” plasma or other contamination could flow back to the process chamber. As a result, the process chamber could be contaminated and the wafers could be ruined. For example, the dry pump at the dry etching system may send a false signal to the system controller. In response, the system controller opens the main valve even though the dry pump has not actually started. As a result, waste gases in the pump line could flow through the main valve into the process chamber and cause contamination.

The present invention provides a system and method that improves the exhaust system of chemical dry etchers. More specifically, the present invention presents an effective system and method for preventing unwanted gases from flowing back into the processing chamber.

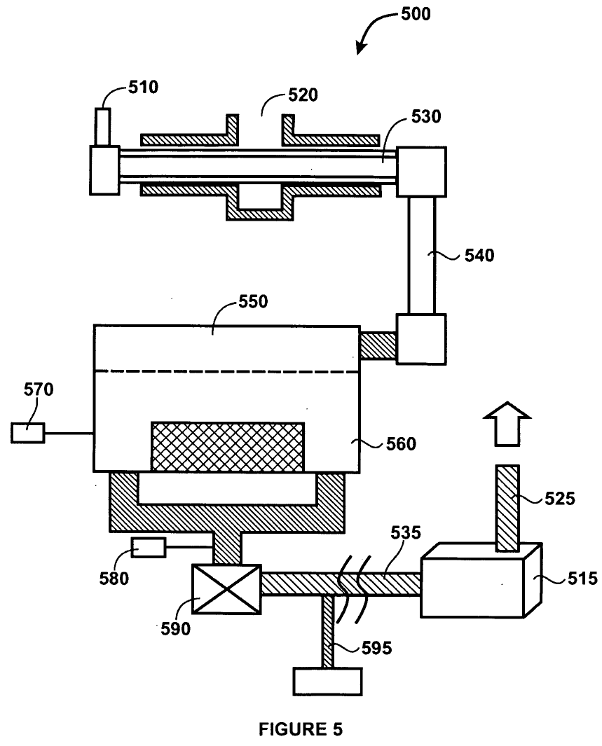

FIG. 5 is a simplified diagram illustrating an improved chemical dry etcher according to an embodiment of the present invention. This diagram is merely an example, which should not unduly limit the scope of the claims. One of ordinary skill in the art would recognize many variations, alternatives, and modifications.

As shown on FIG. 5, the chemical dry etcher 500 includes a gas inlet 510, a quartz tube 530, a microwave source 520, a teflon transport 540, a nozzle 550, a process chamber 560, a Baratron gauge controller 570, a Pirani gauge 580, a main valve 590, a pump line transport 535, a dry pump 515, and pressure gauge 595, and a system exhaust 525.

According to an embodiment, when the chemical dry etcher 100 operates, a gas enters the gas inlet 510. For example, a gas could be various type of gases, including O₂, CF₄, etc. Next the gas enters the quartz tube 530. When the gas is in the quartz tube 530, the microwave source 520 emits microwaves on the gas. As an example, microwaves have a frequency of around 2.45 GHz. After being going through the microwave, the gas becomes a plasma. Then the plasma is transferred through the teflon transport 540 to the nozzle 550. From the nozzle 550, the plasma is applied to one or more wafers in the process chamber 560 for processing. There are many types of process that can be done at the process chamber. For example, processes include etching, corner rounding, bevel etching, resist recess, mask removal, etc. Usually, the pressure is high at the process chamber. According to an embodiment, the Baratron gauge controller 570 is used to monitor and control the pressure. Once the plasma has been used for processing, it is to be disposed. The main valve 590 controls whether, when, and how the plasma is to be disposed. According to an embodiment, the main valve 590 is operated by a system controller. A Pirani gauge 580 is used to monitor the pressure and flow of the plasma at the main valve. Pirani gauges use thermal conductivity to measure pressure and are mainly used for vacuum systems. Generally, the main valve 590 opens after the dry pump 515 has started so that gases, if there is any, in the pump line transport 535 would not enter the process chamber 560 and contaminate. According to an embodiment, a pressure gauge 595 is used to ensure that the dry pump 515 has properly started by measuring the gas pressure within the pump line transport 535. The pressure gauge 595 is connected to the system controller. According to an embodiment, the pressure gauge 595 is capable of measure pressure up to 10 torrs in real time, and is able to send signals associated with pump line transport pressure to the system controller. When the system controllers receives signals from the pressure gauge 525, the system determines, based on measured pressure, if the dry pump 515 has been turned on and operating properly. If the dry pump 515 is operating properly, indicated by proper pressure within the pump line transport 535, the system controller sends a signal to open the main valve 590. Once the main valve 590 opens, the plasma flows through the pump line transport 535 and dry pump 515, and is then disposed at the system exhaust 525.

FIG. 5 merely provides an example, which should not unduly limit the scope of the claims. One of ordinary skill in the art would recognize many variations, alternatives, and modifications. For example, the teflon transport 540 may be replaced by other type of transport. As another example, the Baratron gauge controller 570 may be replaced by other types of gauges with similar applications.

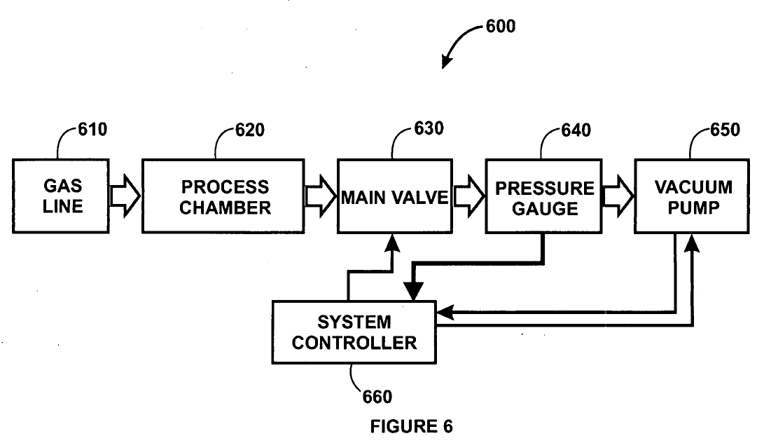

FIG. 6 is a simplified functional block diagram illustrating the system controller flow for the exhaustion portion of the chemical dry etcher 500. This diagram is merely an example, which should not unduly limit the scope of the claims. One of ordinary skill in the art would recognize many variations, alternatives, and modifications. The exhaust system 200 includes a gas line 610, a process chamber 620, a main valve 630, a pressure gauge 640, a dry pump 650, and a system controller 660. The system controller 660 is used to control both the main valve 630 and the dry pump 650. According to an embodiment, the system controller 660 utilizes a feedback system, in which the system controller 660 sends control signals to the main valve 640 and the dry pump 650 based on signals received from the main valve 640, the pressure gauge 640, and the dry pump 650.

FIG. 6 merely provides an example, which should not unduly limit the scope of the claims. One of ordinary skill in the art would recognize many variations, alternatives, and modifications. For example, the system controller 650 could also be connected to the Baratron gauge at the processing chamber and uses signals from the Baratron gauge.

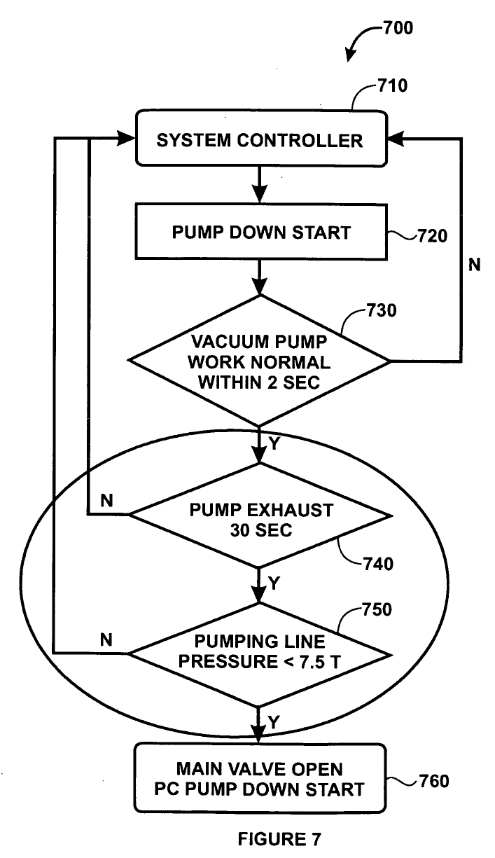

FIG. 7 is a simplified block diagram illustrating the signal control flow for the exhaustion portion of the chemical dry etcher 500. This diagram is merely an example, which should not unduly limit the scope of the claims. One of ordinary skill in the art would recognize many variations, alternatives, and modifications. The control flow 700 begins at step 710 with the system controller sending a start signal to the dry pump. At step 720, the dry pump starts in response to the start signal received from the system controller. After dry pump starts, the dry pump determines whether it is working properly after a predetermined time. According to an embodiment, the dry pump waits for two seconds to determine whether the dry pump is working properly. If the dry pump is not working properly, the dry pump transmits a signal to the system controller. In response, the system may send another start signal or stop the exhaustion process. On the other hand, if the dry pump is working properly, the dry pump stays on for a predetermined time. For example, the dry pump stays on for a period of thirty seconds. Then at step 740, the pressure gauge monitors the pressure at the pump line transport after the predetermined period of time. For example, the pressure gauge monitors the pressure at the pump line transport for thirty seconds. The pressure gauge then sends a signal to the system controller to indicate whether a proper pressure has been reached within the pump line transport. According to an embodiment, a pressure of below 7.5 Torr is deemed proper. For example, if the pressure gauge sends a signal to the system controller indicating that the pressure at the pump line transport is proper, the system controller sends signals to open the main valve and starts exhausting the process chamber. On the other hand, if the pressure gauge sends a signal to the system controller indicating that the pressure at the pump line transport is not proper, the system may terminate or restart the exhaustion sequence.

FIG. 7 merely provides an example, which should not unduly limit the scope of the claims. One of ordinary skill in the art would recognize many variations, alternatives, and modifications. For example, at step 730, instead of the dry pump sending a signal to the system controller, the system controller may simply check whether the dry pump is working properly at a predetermined time. As an example, the system controller sends a signal to the pressure gauge if the system controller does not receive a signal from the dry pump within two seconds. According to another embodiment, the pressure gauge stays on for the duration of the exhaustion sequence and keeps sending signals to the system controller. As an example, the system controller terminates or resets the exhaustion sequence if the pressure reading from the pressure gauge is not within a proper range.

According to an embodiment, the present invention provides a chemical dry etching system, wherein one or more gas is induced into a first chamber (e.g., a quartz tube) and subjected to a microwave power source to cause formation of one or more plasma species. The one or more plasma species is then transferred from the first chamber to a second chamber. At the second chamber, at least one substrate is subjected to the one or more plasma species. Often, the one or more plasma species causes etching at the at least one substrate. The one or more plasma species is then disposed by an exhaust system after the at least one substrate is subjected to the one or more plasma species. The exhaust system includes a system controller. The system controller is configured to receive a plurality of feedback signals and provide a plurality of control signals. For example, the plurality of feedback signals allows the system controller to monitor the status of various components at of the chemical dry etching system. The system controller also includes a pumping device that is configured to turn on in response to a start signal of a plurality of control signals from the system controller and provide a verification signal of the plurality of feedback signals to the system controller. For example, the verification signal indication whether the pumping device is functioning properly. Additionally, the exhaust system includes a first valve, which is configured to open in response to a first signal of the plurality of control signals received from the system controller and close in response to a second signal of the plurality of control signals received from the system controller. In addition, the exhaust system includes a transport. The transport includes a first connection and a second connection. The first connection is connected to the first valve, and the second connection is connected to the pumping device. Moreover, the exhaust system includes a pressure gauge, which is configured to measure a pressure of the transport and provide a pressure signal of the plurality of feedback signals to the system controller. The pressure signal of the plurality of feedback signals is associated with the measured pressured of the transport. For example, the present invention is illustrated according to FIGS. 5 through 7.

According to another embodiment, the present invention provides a chemical dry etching system. At the chemical dry etching system, one or more gas is induced into a first chamber and subjected to a microwave power source to cause formation of one or more plasma species. The one or more plasma species is then transferred from the first chamber to a second chamber. At the second chamber at least one substrate is subjected to the one or more plasma species. The one or more plasma species is then disposed by an exhaust system after the at least one substrate is subjected to the one or more plasma species. A method for operating the exhaust system includes sending a first start signal from a system controller to a pumping device. The pumping device drains a plurality of gas from a transport. The method also includes the step of measuring a pressure in the transport by a pressure gauge after a first predetermined period after sending the first start signal. The pressure gauge is configured to measure the pressure at the transport. The method additionally includes the step of obtaining a plurality of data associated with the pressure by the system controller. Moreover, the method includes the step of determining whether the pressure is below a predetermined threshold pressure. For example, the present invention is illustrated according to FIGS. 5 through 7.

According to another embodiment, the present invention provides a method of manufacturing an integrated circuit device. The method includes providing a semiconductor wafer. The semiconductor wafer includes a surface region. The method additionally includes the step of using a plurality of plasma to form one or more portions of the surface region. The method also includes the step of disposing the plurality of plasma by an exhaust system after a first predetermined period. The exhaust system includes a system controller. The disposing the plurality of plasma includes the step of sending a first start signal from a system controller to a pumping device. The pumping device drains a plurality of gas from a transport. The disposing the plurality of plasma also includes measuring a pressure in the transport by a pressure gauge after a first predetermined period after sending the first start signal. The pressure gauge is configured to measure the pressure at the transport. Additionally, the disposing the plurality of plasma includes obtaining a plurality of data associated with the pressure by the system controller. In addition, the disposing the plurality of plasma includes determining whether the pressure is below a predetermined range of pressure values. For example, the present invention is illustrated according to FIGS. 5 through 7.

According to another embodiment, the present invention provides a method for performing an etching process for manufacture of integrated circuits. The method includes providing a semiconductor wafer. The semiconductor wafer includes a layer to be etched into a plasma chamber. The method also includes the step of maintaining the semiconductor wafer in a predetermined environment. For example, the predetermine environment is a vacuum environment. In addition, the method includes subjecting a portion of the layer to a plasma environment. The plasma environment includes one or more plasma species. For example, the plasma species are used to perform etching. The method also includes monitoring a pressure condition within a first transport device using a sensing device. The sensing device is spatially configured between a valve and a pumping device. The valve is coupled to a second exhaust coupled to the plasma chamber. The method additionally includes determining if the pressure condition within the first exhaust is within a predetermined condition. Moreover, the method includes removing the one or more plasma species through the first exhaust, through the valve, and through the second exhaust if the pressure condition within the first exhaust is within the predetermined condition. For example, the present invention is illustrated according to FIGS. 5 through 7.

According to certain embodiments, the present invention provides a dry etching system that is capable of effectively preventing contamination during the process of dry etching. For example, unwanted gases are prevented from entering into the process chamber of a chemical dry etcher and contaminating the wafers therein. According to an embodiment, the present invention is compatible with existing chemical dry etching processes.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. In a chemical dry etching system, wherein one or more gas is induced into a first chamber and subjected to a microwave power source to cause formation of one or more plasma species, the one or more plasma species being transferred from the first chamber to a second chamber, wherein at the second chamber at least one substrate is subjected to the one or more plasma species, the one or more plasma species being disposed by an exhaust system after the at least one substrate is subjected to the one or more plasma species, the exhaust system comprising:
a system controller being configured to receive a plurality of feedback signals and provide a plurality of control signals;
a pumping device being configured to turn on in response to a start signal of a plurality of control signals from the system controller and provide a verification signal of the plurality of feedback signals to the system controller;
a first valve being configured to open in response to a first signal of the plurality of control signals received from the system controller and close in response to a second signal of the plurality of control signals received from the system controller;
a transport including a first connection and a second connection, wherein the first connection is connected to the first valve, and the second connection is connected to the pumping device;
a pressure gauge being configured to measure a pressure of the transport and provide a pressure signal of the plurality of feedback signals to the system controller, wherein the pressure signal of the plurality of feedback signals is associated with the measured pressured of the transport.

2. The exhaust system of claim 1 wherein the first chamber is a quartz tube.

3. The exhaust system of claim 1 wherein the first valve comprises a Pirani gauge.

4. The exhaust system of claim 1 wherein the pumping device is a dry pump.

5. The exhaust system of claim 1 wherein the pressure gauge is configured to measure the pressure of the transport continuously in real time.

6. The exhaust system of claim 1 wherein the pressure gauge is capable of measuring up to 10 Torrs of pressure.

7. The exhaust system of claim 1 wherein the system control provides a restart signal to the pumping device in response to the verification signal of the plurality of feedback signals indicating that the pumping device is not turned on.

8. The exhaust system of claim 1 wherein the system control provides a restart signal to the pumping device in response to the verification signal of the plurality of feedback signals indicating that the pumping device is not turned on.

9. The exhaust system of claim 1 wherein the system control provides a third signal of the plurality of control signals to stop the exhaust system in response to the verification signal of the plurality of feedback signals indicating that the pumping device is not turned on.

10. The exhaust system of claim 1 wherein the second chamber comprises a process chamber.

11. The exhaust system of claim 10 wherein the process chamber comprises a process chamber exhaust.

12. The exhaust system of claim 11 wherein the process chamber exhausts is configured to start in response to the first signal of the plurality of control signals.

13. In a chemical dry etching system, wherein one or more gas is induced into a first chamber and subjected to a microwave power source to cause formation of one or more plasma species, the one or more plasma species being transferred from the first chamber to a second chamber, wherein at the second chamber at least one substrate is subjected to the one or more plasma species, the one or more plasma species being disposed by an exhaust system after the at least one substrate is subjected to the one or more plasma species, a method for operating the exhaust system comprises:
sending a first start signal from a system controller to a pumping device, wherein the pumping device drains a plurality of gas from a transport;
measuring a pressure in the transport by a pressure gauge after a first predetermined period after sending the first start signal, wherein the pressure gauge is configured to measure the pressure at the transport;
obtaining a plurality of data associated with the pressure by the system controller;
determining whether the pressure is below a predetermined threshold pressure.

14. The method of claim 13 further comprising sending a second start signal to the pumping device if the pressure is not below the predetermined threshold pressure.

15. The method of claim 13 further comprising terminating the exhaustion system if the pressure is not below the predetermined threshold pressure.

16. The method of claim 13 further comprising opening a first valve if the pressure is below the predetermined threshold pressure.

17. The method of claim 13 further comprising sending a second start signal from the system controller to the second chamber if the pressure is below the predetermined threshold pressure.

18. The method of claim 13 wherein the threshold pressure is 7.5 Torr.

19. The method of claim 13 further comprising sending a verification signal from the pumping device to the system controller indicating whether the pumping device is turned on after a second predetermined period.

20. The method of claim 19 further comprising sending a second start signal to the pumping device if the verification signal indicates that the pumping device is not turned on.

21. The method of claim 19 further comprising terminating the exhaustion system if the verification signal indicates that the pumping device is not turned on.

22. A method of manufacturing an integrated circuit device, the method comprising:
providing a semiconductor wafer, the semiconductor wafer including a surface region;
using a plurality of plasma species to form one or more portions of the surface region;
removing the plurality of plasma species by an exhaust system after a first predetermined period, the exhaust system including a system controller, wherein the disposing the plurality of plasma comprises:
sending a first start signal from a system controller to a pumping device, wherein the pumping device drains a plurality of gas from a transport;
measuring a pressure in the transport by a pressure gauge after a first predetermined period after sending the first start signal, wherein the pressure gauge is configured to measure the pressure at the transport;
obtaining a plurality of data associated with the pressure by the system controller;
determining whether the pressure is below a predetermined range of pressure values.

23. The integrated circuited device manufactured by the method of claim 22, wherein the integrated circuit device is associated with a channel length of less than 120 nm.

24. A method for performing an etching process for manufacture of integrated circuits, the method comprising:
providing a semiconductor wafer, the semiconductor wafer including a layer to be etched into a plasma chamber;
maintaining the semiconductor wafer in a predetermined environment;
subjecting a portion of the layer to a plasma environment, the plasma environment including one or more plasma species;
monitoring a pressure condition within a first transport device using a sensing device, the sensing device being spatially configured between a valve and a pumping device, the valve being coupled to a second exhaust coupled to the plasma chamber;
determining if the pressure condition within the first exhaust is within a predetermined condition; and
removing the one or more plasma species through the first exhaust, through the valve, and through the second exhaust if the pressure condition within the first exhaust is within the predetermined condition.

25. The method of claim 24 wherein the removing comprises opening the valve, which is normally closed, to an open position to cause the one or more plasma species to be removed from the plasma chamber.

26. The method of claim 24 wherein the pressure condition is a first vacuum condition, the first vacuum condition being lower in magnitude than a vacuum condition in the plasma chamber.

27. The method of claim 24 wherein the pressure condition is provided by the pumping device.
